(19) United States
(12) Patent Application Publication
(10) Pub. No.: US 2022/0356557 A1
(43) Pub. Date: Nov. 10, 2022

(54) FE-PT-BN-BASED SPUTTERING TARGET AND METHOD FOR MANUFACTURING SAME

(71) Applicant: TANAKA KIKINZOKU KOGYO K.K., Tokyo (JP)

(72) Inventors: Takamichi Yamamoto, Ibaraki (JP); Masahiro Nishiura, Ibaraki (JP); Kenta Kurose, Ibaraki (JP); Hironori Kobayashi, Ibaraki (JP); Takanobu Miyashita, Ibaraki (JP); Tomoko Matsuda, Ibaraki (JP)

(21) Appl. No.: 17/623,511

(22) PCT Filed: Apr. 7, 2020
(86) PCT No.: PCT/JP2020/015625

§ 371 Date: Dec. 28, 2021

(30) Foreign Application Priority Data
Jun. 28, 2019 (JP) 2019-121702

(51) Int. Cl. C23C 14/34; C22C 38/00; C22C 33/02

(52) U.S. Cl. CPC C23C 14/3414; C22C 38/007; C22C 38/002; C22C 38/001; C22C 33/02

(57) ABSTRACT

Provided is an Fe—Pt—BN-based sputtering target that has a high relative density and that suppresses particle generation.

The Fe—Pt—BN-based sputtering target has, as a residue after dissolution in aqua regia measured by a procedure below, the particle size distribution in which D90 is 5.5 μm or less and a proportion of fine particles smaller than 1 μm is 35% or less. The procedure includes: (1) cutting out an about 4 mm-square sample piece from the sputtering target, followed by pulverizing to prepare a pulverized product; (2) classifying the pulverized product using sieves of 106 μm and 300 μm in opening size and collecting a powder that has passed through the 300 μm sieve and remained on the 106 μm sieve; (3) immersing the powder in aqua regia heated to 200° C. to prepare a residue-containing solution in which the powder has been dissolved; (4) filtering the residue-containing solution through a 5A filter paper specified in JIS P 3801 and drying a residue on the filter paper at 80° C. to prepare a residue powder; (5) dispersing the residue powder in water containing a surfactant to prepare a sample solution; and (6) setting the sample solution in a particle size analyzer and measuring the particle size distribution.

### TECHNICAL FIELD

The present invention relates to a BN-containing sputtering target to be used for producing a magnetic thin film as well as a production method therefor and particularly relates to an Fe—Pt—BN-based sputtering target containing Fe, Pt, and BN (boron nitride) as well as a production method therefor.

### BACKGROUND ART

As a sputtering target for producing a granular magnetic thin film of a magnetic recording medium in a hard disk drive or the like, there has been used a sintered compact containing a ferromagnetic metal of Fe or Co as a main component and a nonmagnetic material, such as SiO₂ or other oxides, B (boron), C (carbon), or BN (boron nitride). Although exhibiting excellent performance as a lubricant, BN has problems, for example, of having difficulty in producing a high-density sintered compact due to inferior sinterability, of generating particles during sputtering and thereby lowering the product yield, and of exhibiting poor machinability.

To resolve these problems, there have been proposed, for example, a method of improving sinterability through alloying of BN with SiO₂ (Patent Literature (PTL) 1: Japanese Patent No. 5567227), a method of lowering the oxygen content of a sputtering target by using Fe—Pt alloy powder to suppress formation of iron oxide (PTL 2: Japanese Patent No. 5689543), and a method of aligning the crystal orientation of hexagonal BN through mixing of hexagonal BN with metal raw material powders that have been pulverized into sheet shapes or flakes (PTL 3: Japanese Patent No. 5913620).

Japanese Patent No. 5567227 discloses that a high-density sputtering target which reduces particles generated during sputtering is provided by dispersing hexagonal BN grains as a nonmagnetic material, together with SiO₂ grains, in a matrix of an Fe—Pt based alloy and discloses that the sinterability of hexagonal BN can be enhanced significantly by incorporating BN and SiO₂ in the mutually diffused state. As a concrete production method, it is disclosed that raw material powders of Fe, Pt, SiO₂, and BN are mixed using a stirred media mill at 300 rpm for 2 hours and the resulting mixed powder is hot pressed and then subjected to hot isostatic pressing. Moreover, it is disclosed that the resulting sintered compact of Fe—Pt based magnetic material has, on the cross-section perpendicular to the pressed surface, an X-ray diffraction peak intensity ratio of the (002) plane of hexagonal BN relative to the background intensity of 1.50 or more and an X-ray diffraction peak intensity ratio of the (101) plane of cristobalite, which is crystallized SiO₂, of 1.40 or less. Further, it is disclosed that the Comparative Examples (Fe—Pt—BN based, Fe—Pt—BN-oxide based, Fe—Pt—BN-nonmagnetic material based), which were produced under the same conditions but in the absence of SiO₂, have a considerably increased number of particles as many as 645 or more.

Japanese Patent No. 5689543 discloses that a sintered compact of Fe—Pt—BN based magnetic material having an oxygen content as low as 4,000 wtppm or less can be prepared by using Fe—Pt alloy powder and discloses that the prepared sintered compact exhibits satisfactory machinability and thus can suppress cracking or chipping, thereby reducing the occurrence of abnormal discharge or particle generation. As a concrete production method, it is disclosed that BN powder and Fe—Pt alloy powder having a particle size of 0.5 μm or more and 10 μm or less are fed into a mortar and mixed uniformly and the resulting mixed powder is hot pressed and then subjected to hot isostatic pressing. Here, using Fe—Pt alloy powder having a particle size of 0.5 μm or more and 10 μm or less is a prerequisite for making the form of Fe less susceptible to oxidation. Further, it is disclosed that the Comparative Examples (Fe—Pt—BN based, Fe—Pt—BN-nonmagnetic material based), which were produced under the same conditions except for mixing Fe powder, Pt powder, and BN powder using a stirred media mill at 300 rpm for 2 hours, exhibited an oxygen content as high as 11,500 wtppm or more and caused chipping.

Japanese Patent No. 5913620 discloses that hexagonal BN having a two-dimensional crystal structure affects electric conductivity and causes abnormal discharge when the crystal orientation of hexagonal BN is randomly aligned within a sintered compact and discloses that, for this reason, stable sputtering is made possible by aligning the crystal orientation of hexagonal BN in one direction. Specifically, it is disclosed, in an Fe—Pt based sintered compact sputtering target, that a ratio of an X-ray diffraction peak intensity of the (002) plane of hexagonal BN on a surface horizontal to the sputtering surface to an X-ray diffraction peak intensity of the (002) plane of hexagonal BN on a cross-section perpendicular to the sputtering surface is set to 2 or more and disclosed that the hexagonal BN phase on the cross-section perpendicular to the sputtering surface is formed into flakes or sheet shapes having an average thickness of 30 μm or less. Moreover, as a concrete production method, it is disclosed that Fe—Pt alloy powder is treated using a stirred media mill at 300 rpm for 2 hours into an average particle size of 10 μm, then mixed with hexagonal BN flakes having an average particle size of 8 μm in a V-type mixer, and further mixed in a mortar or with a sieve of 150 μm in opening size and the resulting mixed powder is hot-pressed and then subjected to hot isostatic pressing. Further, it is disclosed that the Comparative Examples (Fe—Pt—BN based, Fe—Pt—BN-nonmagnetic material based, Fe—Pt—BN-oxide based), which were produced under the same conditions except for directly mixing unpretreated Fe—Pt alloy powder with BN powder, exhibit a considerably increased number of particles as many as 616 or more.

As in the foregoing, PTL 1 to 3 disclose that a sputtering target obtained by a production method including mixing Fe powder, Pt powder, and BN powder in a stirred media mill at 300 rpm for 2 hours and subjecting the resulting mixed powder to hot pressing and hot isostatic pressing is still unable to reduce the number of particles.

### CITATION LIST

### Patent Literature

PTL 1: Japanese Patent No. 5567227

PTL 2: Japanese Patent No. 5689543

PTL 3: Japanese Patent No. 5913620

### SUMMARY OF INVENTION

### Technical Problem

An object of the present invention is to resolve the problem of particle generation in an Fe—Pt—BN-based sputtering target that has a high relative density by an approach different from the inventions disclosed in PTL 1 to 3.

### Solution to Problem

The present inventors attributed particle generation in an Fe—Pt—BN-based sputtering target to aggregation of BN particles and then found possible to provide an Fe—Pt—BN-based sputtering target that can suppress particle generation by uniformly and finely dispersing BN particles while avoiding aggregation of BN particles.

According to the present invention, an Fe—Pt—BN-based sputtering target of the following embodiments is provided.

[1] An Fe—Pt—BN-based sputtering target containing Fe, Pt, and BN, where a residue after dissolution in aqua regia has the particle size distribution in which a volume-based 90% size (D90) is 5.5 μm or less and a proportion of fine particles smaller than 1 μm is 35% or less when the sputtering target is measured by a procedure below including:

(1) cutting out a 4 mm-square sample piece from the sputtering target and pulverizing the sample piece to prepare a pulverized product;

(2) classifying the pulverized product using sieves of 106 μm and 300 μm in opening size and collecting a powder that has passed through the 300 μm sieve and remained on the 106 μm sieve;

(3) immersing the powder in aqua regia heated to 200° C. to prepare a residue-containing solution in which the powder has been dissolved;

(4) filtering the residue-containing solution through a 5A filter paper specified in JIS P 3801 and drying a residue on the filter paper at 80° C. to prepare a residue powder;

(5) dispersing the residue powder in water containing a surfactant to prepare a sample solution; and

(6) setting the sample solution in a particle size analyzer and measuring the particle size distribution.

[2] The Fe—Pt—BN-based sputtering target according to [1] above, containing 10 mol % or more and 55 mol % or less of Pt.

[3] The Fe—Pt—BN-based sputtering target according to [1] or [2] above, further containing one or more elements selected from Ag, Au, B, Co, Cr, Cu, Ge, Ir, Ni, Pd, Rh, and Ru; and/or

one or more nonmetal components selected from C and an oxide of Si, Ti, Ta, or Zr.

[4] The Fe—Pt—BN-based sputtering target according to any one of [1] to [3] above, containing 10 mol % or more and 55 mol % or less in total of BN and one or more nonmetal components.

[5] A production method for the Fe—Pt—BN-based sputtering target according to any one of [1] to [4] above, including

feeding Fe powder, Pt powder, and BN powder into a stirred media mill and mixing at 100 rpm or more and 200 rpm or less for 2 hours or more and 6 hours or less to prepare a raw material powder mixture;

collecting, from the raw material powder mixture, a power that has passed through a sieve of 300 μm in opening size; and

sintering the powder.

[6] The production method according to [5] above, where the sintering is performed at a sintering temperature of 600° C. or higher and 1,200° C. or lower and a sintering pressure of 30 MPa or more and 200 MPa or less.

### Advantageous Effects of Invention

An Fe—Pt—BN-based sputtering target of the present invention has a relative density of 90% or more and can reduce the number of particles generated during magnetron sputtering.

### BRIEF DESCRIPTION OF DRAWINGS

FIG. 1 is a metallurgical microscope image (1,000×) of the Fe—Pt—BN-based sintered compact in Example 2.

FIG. 2 is a metallurgical microscope image (1,000×) of the Fe—Pt—BN-based sintered compact in Comparative Example 3.

### DESCRIPTION OF EMBODIMENTS

Hereinafter, the present invention will be described in detail with reference to the attached drawings. However, the present invention is by no means limited to these descriptions.

An Fe—Pt—BN-based sputtering target of the present invention is characterized in that a residue after dissolution in aqua regia has the particle size distribution in which a volume-based 90% size (D90) is 5.5 μm or less and a proportion of fine particles smaller than 1 μm is 35% or less when measured by a procedure below including:

(1) cutting out an about 4 mm-square sample piece from the sputtering target and pulverizing the sample piece to prepare a pulverized product;

(2) classifying the pulverized product using sieves of 106 μm and 300 μm in opening size and collecting a powder that has passed through the 300 μm sieve and remained on the 106 μm sieve;

(3) immersing the powder in aqua regia (hydrochloric acid:nitric acid=3:1) heated to 200° C. to prepare a residue-containing solution in which the powder has been dissolved;

(4) filtering the residue-containing solution through a 5A filter paper (for example, analytical filter paper No. 5A from Toyo Roshi Kaisha, Ltd.) specified in JIS P 3801 and drying a residue on the filter paper at 80° C. to prepare a residue powder;

(5) dispersing the residue powder in water containing a surfactant to prepare a sample solution; and

(6) setting the sample solution in a particle size analyzer and measuring the particle size distribution.

The surfactant used for preparing a sample solution is not particularly limited provided that the surfactant can prevent aggregation of a residue powder in water and disperse the residue powder in the state separated into individual particles. In the Examples section described hereinafter, 0.15 g of a surfactant with 15% concentration containing a sodium linear alkylbenzene sulfonate and a polyoxyethylene alkyl ether was used by diluting in 30 mL of water.

In the present invention, a “dissolution residue” is a solid component excluding metals from the components of a sputtering target and indicates a residue obtained by dissolving in aqua regia [3:1 mixture (volume ratio) of concentrated hydrochloric acid (special grade) and concentrated nitric acid (special grade)].

When a sputtering target contains Ag (silver) as a metal component, the powder is first immersed in nitric acid to dissolve and remove Ag since Ag does not dissolve in aqua regia. The undissolved residue is then immersed in aqua regia, and the resulting undissolved residue is a “dissolution residue.” In a similar manner, when a sputtering target contains Cr (chromium) as a metal component, the powder is first immersed in hydrochloric acid to dissolve and remove Cr since Cr does not dissolve in aqua regia. The undissolved residue is then immersed in aqua regia, and the resulting undissolved residue is a “dissolution residue.”

Since Fe, Pt, and other metal components, among the components of an Fe—Pt—BN-based sputtering target, dissolve in aqua regia, the residue is a nonmetal component, such as BN, C, an oxide, or a nitride. Such dissolution residues are nonmagnetic material particles that cause particle generation during sputtering.

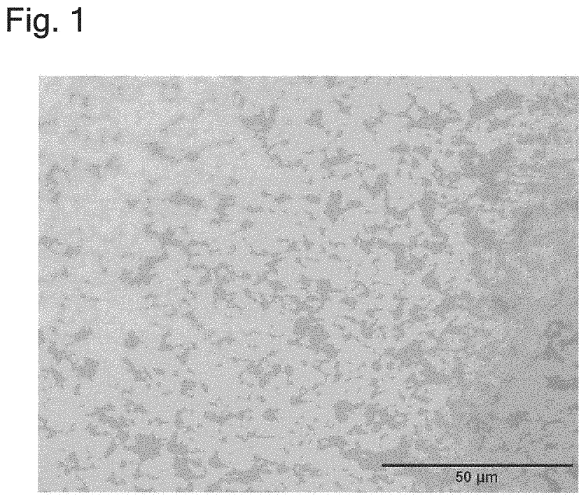

An Fe—Pt—BN-based sputtering target of the present invention is characterized in that a residue after dissolution in aqua regia has the particle size distribution in which a volume-based 90% size (D90) is 5.5 μm or less and a proportion of fine particles smaller than 1 μm is 35% or less. In other words, 55% or more nonmetal components of the Fe—Pt—BN-based sputtering target of the present invention are distributed within the particle size range of 1 μm or more and 5.5 μm or less; and the content of excessively large particles or excessively small particles is low. The metallographic image of FIG. 1 also reveals that nonmetal particles represented by dark gray to black lack excessively large or excessively small particles and fall within a certain range.

In the Fe—Pt—BN-based sputtering target of the present invention, a residue after dissolution in aqua regia has a volume-based 90% size (D90) of 5.5 μm or less, preferably 5.3 μm or less, and more preferably 5.2 μm or less. Moreover, the proportion of fine particles smaller than 1 μm is 35% or less and more preferably 34% or less. When the residue after dissolution in aqua regia, which is a nonmetal component, has a volume-based 90% size (D90) exceeding 5.5 μm, the number of particles during sputtering increases considerably. Moreover, when the proportion of fine particles smaller than 1 μm increases exceeding 35%, the practical use as a sputtering target is impossible due to low relative density. Further, when fine particles smaller than 1 μm increase, such fine particles aggregate to form large nonmetal component regions within the texture of a sputtering target, thereby causing particle generation.

The Fe—Pt—BN-based sputtering target of the present invention may further contain one or more elements selected from Ag, Au, B, Co, Cr, Cu, Ge, Ir, Ni, Pd, Rh, and Ru; an oxide of Si, Ti, Ta, or Zr; or C. The oxide is preferably SiO, SiO₂, Si₃O₂, TiO, TiO₂, Ti₂O₃, Ta₂O₅, or ZrO₂ and more preferably SiO₂, TiO₂, Ta₂O₅, or ZrO₂ and may include one or two or more oxides.

The amount of Pt may be set to 10 mol % or more and 55 mol % or less and preferably 15 mol % or more and 50 mol % or less based on the entire Fe—Pt—BN-based sputtering target. Within these ranges, it is possible to satisfactorily maintain the magnetic characteristics of the Fe—Pt-based alloy.

The total amount of Ag, Au, B, Co, Cr, Cu, Ge, Ir, Ni, Pd, Rh, and Ru may be set to 0 mol % or more and 20 mol % or less and preferably 0 mol % or more and 15 mol % or less based on the entire Fe—Pt—BN-based sputtering target. Within these ranges, it is possible to satisfactorily maintain the magnetic characteristics of the Fe—Pt-based alloy.

BN, oxides, and C as nonmetal components act as grain boundary materials for a granular magnetic thin film of a magnetic recording medium. The total amount of BN, oxides, and C is preferably 10 mol % or more and 55 mol % or less, more preferably 15 mol % or more and 50 mol % or less, and particularly preferably 20 mol % or more and 45 mol % or less based on the entire Fe—Pt—BN-based sputtering target.

The content of BN is preferably 10 mol % or more and 55 mol % or less, preferably 15 mol % or more and 50 mol % or less, and particularly preferably 20 mol % or more and 45 mol % or less based on the entire Fe—Pt—BN-based sputtering target. Within these ranges, BN acts as a grain boundary material for a granular magnetic thin film of a magnetic recording medium.

The content of an oxide is preferably 0 mol % or more and 20 mol % or less and particularly preferably 0 mol % or more and 15 mol % or less based on the entire Fe—Pt—BN-based sputtering target. Within these ranges, an oxide, together with BN or C, acts as a grain boundary material for a granular magnetic thin film of a magnetic recording medium.

The content of C is preferably 0 mol % or more and 20 mol % or less and particularly preferably 0 mol % or more and 15 mol % or less based on the entire Fe—Pt—BN-based sputtering target. Within these ranges, C, together with BN or oxides, acts as a grain boundary material for a granular magnetic thin film of a magnetic recording medium.

As Fe powder, a powder having an average particle size of 1 μm or more and 10 μm or less is preferably used. An excessively small average particle size is not preferable since the risk of ignition or the concentration of incidental impurities is likely to increase. Meanwhile, an excessively large average particle size is also not preferable since uniform dispersing of BN is impossible.

As Pt powder, a powder having an average particle size of 0.1 μm or more and 10 μm or less is preferably used. An excessively small average particle size is not preferable since the concentration of incidental impurities is likely to increase. Meanwhile, an excessively large average particle size is also not preferable since uniform dispersing of BN is impossible.

As BN powder, a powder having an average particle size of 2 μm or more and 10 μm or less is preferably used. An average particle size outside this range is not preferable since a desirable dispersion state cannot be achieved.

As C powder, a powder having an average particle size of 2 μm or more and 10 μm or less is preferably used. An average particle size outside this range is not preferable since a desirable dispersion state cannot be achieved.

As metal powders used as other additional components, powders having an average particle size of 0.1 μm or more and 20 μm or less are preferably used. An excessively small average particle size is not preferable since the concentration of incidental impurities is likely to increase. Meanwhile, an excessively large average particle size is also not preferable since uniform dispersing is impossible.

As oxide powders used as other additional components, powders having an average particle size of 1 μm or more and 5 μm or less are preferably used. An average particle size outside this range is not preferable since a desirable dispersion state cannot be achieved.

The Fe—Pt—BN-based sputtering target of the present invention can be produced by feeding Fe powder, Pt powder, and BN powder into a stirred media mill and mixing at 100 rpm or more and 200 rpm or less for 2 hours or more and 6 hours or less to prepare a raw material powder mixture; collecting, from the raw material powder mixture, a power that has passed through a sieve of 300 μm in opening size; and sintering the powder. An excessively low rotation number of the stirred media mill is not preferable since uniform dispersing of BN is impossible. Meanwhile, an excessively high rotation number is also not preferable since a desirable dispersion state cannot be achieved due to formation of fine particles.

The sintering is desirably performed at a sintering temperature of 600° C. or higher and 1,200° C. or lower and preferably 700° C. or higher and 1,100° C. or lower and a sintering pressure of 30 MPa or more and 200 MPa or less and preferably 50 MPa or more and 100 MPa or less. An excessively low sintering temperature is not preferable since there is the risk of lowering relative density. Meanwhile, an excessively high sintering temperature is also not preferable since there is the risk of decomposing BN.

When producing the Fe—Pt—BN-based sputtering target of the present invention, it is preferable not to perform hot isostatic pressing. It is considered that hot isostatic pressing hardens metal components and thus excessively crushes BN particles.

### EXAMPLES

Hereinafter, the present invention will be described specifically by means of Examples and Comparative Examples. The methods for measuring the relative density, the number of particles, and the particle size distribution of each sputtering target in the following Examples and Comparative Examples are as follows.

[Relative Density]

The density is measured by the Archimedes method using pure water as a replacement liquid. An actual density (g/cm³) is determined by measuring the mass of a sintered compact; measuring the buoyant force of the sintered compact (=volume of sintered compact) in the state of floating on the replacement liquid; and dividing the mass (g) of the sintered compact by the volume (cm³) of the sintered compact. The percentage (actual density/theoretical density×100) to a theoretical density that is calculated on the basis of the composition of the sintered compact is a relative density.

[Number of Particles]

A sintered compact is processed into a diameter of 153 mm and a thickness of 2 mm and bonded using indium to a Cu backing plate having a diameter of 161 mm and a thickness of 4 mm to prepare a sputtering target. The resulting sputtering target is fixed to a magnetron sputtering apparatus. After discharging in an Ar gas atmosphere at an output of 500 W and a gas pressure of 1 Pa for 4 hours, the number of particles adhered onto a substrate during sputtering for 40 seconds is determined by a particle counter.

[Particle Size Distribution]

An about 4 mm-square sample piece is cut out from a sputtering target and pulverized with a crusher (Wonder Blender from Osaka Chemical Co., Ltd.). The pulverized powder is classified at the maximum amplitude for 1 minute using an electromagnetic sieve shaker (MS-200 from Ito Seisakusho Co., Ltd.) with sieves of 106 μm and 300 μm in opening size set on a tray to collect a powder that has passed through the 300 μm sieve and remained on the 106 μm sieve. The collected powder is immersed in aqua regia [100 mL: special grade hydrochloric acid (product No. 18078-00) and special grade nitric acid (specific gravity of 1.38, product No. 28163-00) from Kanto Chemical Co., Inc. were mixed in a volume ratio of 3:1] heated on a hot plate at 200° C. for 1 hour until the termination of reactions (first time). The extracted residue is immersed for 1 hour in 100 mL of new aqua regia heated on a hot plate at 200° C. (second time). After confirming the termination of reactions, a residue in aqua regia is extracted. The extracted residue is immersed for 1 hour in 100 mL of new aqua regia heated on a hot plate at 200° C. (third time). The third aqua regia containing a residue is filtered through a No. 5A (JIS P 3801 5A) filter paper (pore size of 7 μm), and a residue on the filter paper is washed with pure water into a beaker and filtered again through a No. 5A filter paper. The filter paper is spread on a hot plate at 80° C. and dried for 15 minutes to collect a residue powder. To a 100 mL beaker, 10 mg of the residue powder, 30 mL of water, and 0.15 g of a 15% surfactant (sodium linear alkylbenzene sulfonate, polyoxyethylene alkyl ether) are fed and subjected to dispersing treatment for 5 minutes using an ultrasonic homogenizer [US-150T (rated output of 150 W) from Nihon Seiki Kaisha Ltd.] at V-LEVEL adjusted to 200 to 300 μA to obtain a sample solution. The sample solution is measured twice with a particle size analyzer [MT-3300EXII (laser diffraction/scattering mode, measurement range of 0.02 to 2,000 μm) from MicrotracBEL Corp.] under the conditions shown in Table 1. When two measured values fall outside acceptable error ranges, the measurement is performed again, where the acceptable error ranges are ±0.1 μm, ±0.2 μm, and ±1 μm when each 10% size (D10), 50% size (D50), and 90% size (D90) is 0 μm or more and less than 10 μm, 10 μm or more and less than 40 μm, and 40 μm or more, respectively. On the data analysis window of the particle size analyzer, “1 μm pass” (cumulative % value of particles that has passed through 1 μm sieve) at “size %” is regarded as “<1 μm (%).”

TABLE 1
Particle Size Analyzer Conditions

| Particle | Transmissive | Transmission |
|---|---|---|
| conditions | Refractive index | 1.81 |
| | Shape | Non-spherical |
| Solvent | Solvent | Water |
| conditions | Solvent refractive index | 1.333 |
| Time | SetZero time | 30 seconds |
| | Measurement time | 30 seconds |
| | Repetition times | 2 |
| Analysis option | Analysis mode | MT3000 |
| Display settings | Particle size classification | Standard |
| | Distribution display | Volume |
| Circulator | Sampling | SDC |
| | Washing (times) | 3 |
| | Flow rate (%) | 60 |
| | Degassing (times) | 3 |

### Example 1

To have the composition of Fe-31.5Pt-30BN (in mol %, Fe for the balance; the same applies to the Examples and the Comparative Examples hereinafter), 190.28 g of Fe powder having an average particle size of 7 μm, 543.83 g of Pt powder having an average particle size of 1 μm, and 65.90 g of BN powder having an average particle size of 4 μm were fed into a stirred media mill (media: zirconia balls) and mixed at 150 rpm for 4 hours to yield a mixed powder. The resulting mixed powder was classified with a sieve of 300 μm in opening size, and the powder that had passed through the sieve was sintered under conditions of a sintering pressure of 66 MPa, a sintering temperature of 900° C., and a holding time of 1 hour to yield a sintered compact.

After the relative density was measured, the sintered compact was processed into a sputtering target to measure the number of particles. Subsequently, an about 4 mm-square sample piece was cut out from the sputtering target, and the particle size distribution of a residue after dissolution in aqua regia was measured. The relative density was 93.8%, and the number of particles was 53. The residue after dissolution in aqua regia had D90 of 3.71 μm and the proportion of fine particles smaller than 1 μm of 26.12%.

### Example 2

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 4 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 92.9%, and the number of particles was 38. The residue after dissolution in aqua regia had D90 of 3.41 μm and the proportion of fine particles smaller than 1 μm of 28.26%. Further, FIG. 1 shows the metallurgical microscope image (1,000×) of the texture of the sintered compact.

### Example 3

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 2 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 95.6%, and the number of particles was 83. The residue after dissolution in aqua regia had D90 of 5.18 μm and the proportion of fine particles smaller than 1 μm of 12.76%.

### Example 4

To have the composition of Fe-31.5Pt-7Ag-30BN, 145.91 g of Fe powder having an average particle size of 7 μm, 509.70 g of Pt powder having an average particle size of 1 μm, 62.63 g of Ag powder having an average particle size of 10 μm, and 61.76 g of BN powder having an average particle size of 4 μm were fed into a stirred media mill (media: zirconia balls) and mixed at 150 rpm for 4 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 95.2%, and the number of particles was 49. The residue after dissolution in aqua regia had D90 of 3.60 μm and the proportion of fine particles smaller than 1 μm of 27.50%.

### Example 5

To have the composition of Fe-31.5Pt-7Co-30BN, 151.43 g of Fe powder having an average particle size of 7 μm, 528.97 g of Pt powder having an average particle size of 1 μm, 35.51 g of Co powder having an average particle size of 3 μm, and 64.10 g of BN powder having an average particle size of 4 μm were fed into a stirred media mill (media: zirconia balls) and mixed at 150 rpm for 4 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 93.7%, and the number of particles was 41. The residue after dissolution in aqua regia had D90 of 3.19 μm and the proportion of fine particles smaller than 1 μm of 31.25%.

### Example 6

To have the composition of Fe-31.5Pt-7Rh-30BN, 148.33 g of Fe powder having an average particle size of 7 μm, 518.15 g of Pt powder having an average particle size of 1 μm, 60.74 g of Rh powder having an average particle size of 10 μm, and 62.79 g of BN powder having an average particle size of 4 μm were fed into a stirred media mill (media: zirconia balls) and mixed at 150 rpm for 4 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 92.5%, and the number of particles was 43. The residue after dissolution in aqua regia had D90 of 3.75 μm and the proportion of fine particles smaller than 1 μm of 27.24%.

### Example 7

To have the composition of Fe-39Pt-20BN-5Si02, 153.66 g of Fe powder having an average particle size of 7 μm, 581.50 g of Pt powder having an average particle size of 1 μm, 37.94 g of BN powder having an average particle size of 4 μm, and 22.96 g of SiO₂ powder having an average particle size of 2 μm were fed into a stirred media mill (media: zirconia balls) and mixed at 150 rpm for 4 hours to yield a mixed powder. Except for this and for changing the sintering temperature to 1,100° C., a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 97.1%, and the number of particles was 28. The residue after dissolution in aqua regia had D90 of 2.73 μm and the proportion of fine particles smaller than 1 μm of 33.53%.

### Example 8

To have the composition of Fe-35Pt-30BN, 172.79 g of Fe powder having an average particle size of 7 μm, 603.60 g of Pt powder having an average particle size of 1 μm, and 65.83 g of BN powder having an average particle size of 4 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 95.0%, and the number of particles was 67. The residue after dissolution in aqua regia had D90 of 4.38 μm and the proportion of fine particles smaller than 1 μm of 18.12%.

### Example 9

To have the composition of Fe-32.5Pt-35BN, 157.91 g of Fe powder having an average particle size of 7 μm, 551.60 g of Pt powder having an average particle size of 1 μm, and 75.58 g of BN powder having an average particle size of 4 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 94.1%, and the number of particles was 77. The residue after dissolution in aqua regia had D90 of 4.54 μm and the proportion of fine particles smaller than 1 μm of 19.57%.

### Example 10

To have the composition of Fe-27.5Pt-45BN, 129.51 g of Fe powder having an average particle size of 7 μm, 452.40 g of Pt powder having an average particle size of 1 μm, and 94.19 g of BN powder having an average particle size of 4 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 91.4%, and the number of particles was 94. The residue after dissolution in aqua regia had D90 of 4.09 μm and the proportion of fine particles smaller than 1 μm of 23.55%.

### Example 11

To have the composition of Fe-35Pt-20BN-10C, 173.45 g of Fe powder having an average particle size of 7 μm, 605.89 g of Pt powder having an average particle size of 1 μm, 44.05 g of BN powder having an average particle size of 4 μm, and 10.66 g of C powder having an average particle size of 3 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 96.2%, and the number of particles was 61. The residue after dissolution in aqua regia had D90 of 4.38 μm and the proportion of fine particles smaller than 1 μm of 19.94%.

### Example 12

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 95.1%, and the number of particles was 62. The residue after dissolution in aqua regia had D90 of 4.49 μm and the proportion of fine particles smaller than 1 μm of 21.73%.

### Example 13

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 3 hours to yield a mixed powder. Except for this and for changing the sintering temperature to 700° C., a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 93.3%, and the number of particles was 82. The residue after dissolution in aqua regia had D90 of 4.67 μm and the proportion of fine particles smaller than 1 μm of 19.84%.

### Example 14

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 6 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 90.7%, and the number of particles was 33. The residue after dissolution in aqua regia had D90 of 2.70 μm and the proportion of fine particles smaller than 1 μm of 33.88%.

### Example 15

To have the composition of Fe-25Pt-10Au-30BN-10C, 116.99 g of Fe powder having an average particle size of 7 μm, 408.33 g of Pt powder having an average particle size of 1 μm, 165.05 g of Au powder having an average particle size of 1 μm, 62.40 g of BN powder having an average particle size of 4 μm, and 10.06 g of C powder having an average particle size of 3 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 96.1%, and the number of particles was 55. The residue after dissolution in aqua regia had D90 of 4.58 μm and the proportion of fine particles smaller than 1 μm of 19.28%.

### Example 16

To have the composition of Fe-25Pt-10Ag-30BN-10C, 116.89 g of Fe powder having an average particle size of 7 μm, 408.33 g of Pt powder having an average particle size of 1 μm, 90.31 g of Ag powder having an average particle size of 10 μm, 62.34 g of BN powder having an average particle size of 4 μm, and 10.06 g of C powder having an average particle size of 3 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 95.7%, and the number of particles was 49. The residue after dissolution in aqua regia had D90 of 4.62 μm and the proportion of fine particles smaller than 1 μm of 20.83%.

### Example 17

To have the composition of Fe-25Pt-10Cu-30BN-10C, 121.19 g of Fe powder having an average particle size of 7 μm, 423.33 g of Pt powder having an average particle size of 1 μm, 55.16 g of Cu powder having an average particle size of 3 μm, 64.63 g of BN powder having an average particle size of 4 μm, and 10.43 g of C powder having an average particle size of 3 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 95.9%, and the number of particles was 66. The residue after dissolution in aqua regia had D90 of 4.63 μm and the proportion of fine particles smaller than 1 μm of 21.38%.

### Example 18

To have the composition of Fe-25Pt-10Rh-30BN-10C, 119.55 g of Fe powder having an average particle size of 7 μm, 417.61 g of Pt powder having an average particle size of 1 μm, 88.12 g of Rh powder having an average particle size of 10 μm, 63.76 g of BN powder having an average particle size of 4 μm, and 10.28 g of C powder having an average particle size of 3 μm were fed into a stirred media mill (media: zirconia balls) and mixed at 150 rpm for 3 hours to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 94.0%, and the number of particles was 88. The residue after dissolution in aqua regia had D90 of 4.77 μm and the proportion of fine particles smaller than 1 μm of 20.14%.

### Example 19

To have the composition of Fe-25Pt-10Ge-30BN-10C, 112.65 g of Fe powder having an average particle size of 7 μm, 393.51 g of Pt powder having an average particle size of 1 μm, 58.61 g of Ge powder having an average particle size of 10 μm, 60.08 g of BN powder having an average particle size of 4 μm, and 9.69 g of C powder having an average particle size of 3 μm were fed into a stirred media mill (media: zirconia balls) and mixed at 150 rpm for 3 hours to yield a mixed powder. Except for this and for changing the sintering temperature to 700° C., a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 97.0%, and the number of particles was 60. The residue after dissolution in aqua regia had D90 of 4.29 μm and the proportion of fine particles smaller than 1 μm of 19.43%.

### Comparative Example 1

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 30 minutes to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 95.4%, and the number of particles was 563. The residue after dissolution in aqua regia had D90 of 6.34 μm and the proportion of fine particles smaller than 1 μm of 5.21%.

### Comparative Example 2

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 12 hours to yield a mixed powder. Except for this, a sintered compact was produced in the same manner as Example 1 and the relative density was measured. Since the relative density was 87.4%, which is less than 90%, the practical use as a sputtering target was impossible. For this reason, the number of particles was not measured. The particle size distribution of a residue after dissolution in aqua regia was measured using a sample piece cut out from a sputtering target processed from the sintered compact, where D90 was 2.48 μm and the proportion of fine particles smaller than 1 μm was 36.29%.

### Comparative Example 3

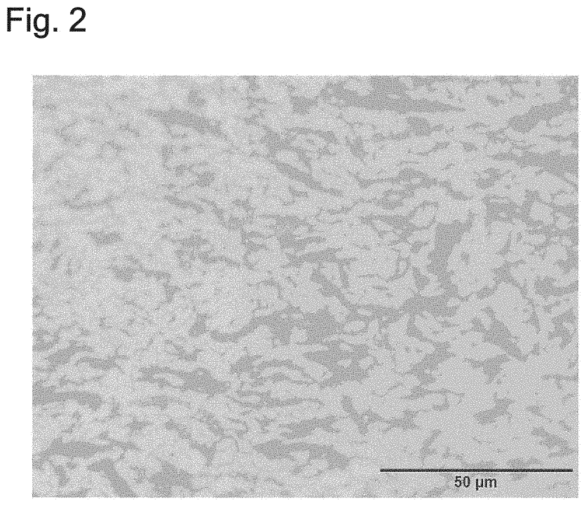

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 300 rpm for 30 minutes to yield a mixed powder. Except for this, a sintered compact was produced in the same manner as Example 1 and, after measurement of the relative density, processed into a sputtering target to measure the number of particles. The particle size distribution of a residue after dissolution in aqua regia was measured using a sample piece cut out from the sputtering target. The relative density was 91.4%, and the number of particles was 713. The residue after dissolution in aqua regia had D90 of 5.72 μm and the proportion of fine particles smaller than 1 μm of 21.85%. Further, FIG. 2 shows the metallurgical microscope image (1,000×) of the texture of the sintered compact.

### Comparative Example 4

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 300 rpm for 2 hours to yield a mixed powder. Except for this, a sintered compact was produced in the same manner as Example 1 and the relative density was measured. Since the relative density was 86.5%, which is less than 90%, the practical use as a sputtering target was impossible. For this reason, the number of particles was not measured. The particle size distribution of a residue after dissolution in aqua regia was measured using a sample piece cut out from a sputtering target processed from the sintered compact, where D90 was 4.57 μm and the proportion of fine particles smaller than 1 μm was 36.58%.

### Comparative Example 5

To have the composition of Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 460 rpm for 6 hours to yield a mixed powder. Except for this, a sintered compact was produced in the same manner as Example 1 and the relative density was measured. Since the relative density was 79.2%, which is less than 90%, the practical use as a sputtering target was impossible. For this reason, the number of particles was not measured. The particle size distribution of a residue after dissolution in aqua regia was measured using a sample piece cut out from a sputtering target processed from the sintered compact, where D90 was 2.35 μm and the proportion of fine particles smaller than 1 μm was 40.16%.

The foregoing results reveal the following. Examples 1 to 19, which exhibit the particle size distribution of a residue in which a volume-based 90% size (D90) is 5.5 μm or less and a proportion of fine particles smaller than 1 μm is 35% or less, have a relative density of 90% or more and the number of particles of less than 100 and hence satisfy both conditions of a high relative density and a small number of particles. Meanwhile, Comparative Examples 1 to 5, in which the particle size distribution does not meet the above-mentioned requirements, fail to satisfy either condition for a relative density or the number of particles. For example, when Example 3 and Comparative Example 1 having the same composition (Fe-30Pt-30BN—C) and almost the same relative density (about 95.5%) are compared, the number of particles is 83 for Example 3 and 563 for Comparative Example 1. This reveals that the number of particles can be reduced to about 1/7 according to the present invention. Moreover, when Example 4 and Comparative Example 1 having an almost equal relative density of about 95% are compared, the number of particles is less than 50 for Example 4 and more than 560 for Comparative Example 1. This reveals that the number of particles can be reduced to about 1/10 according to the present invention.

The comparison of the texture between sintered compacts having the same composition (Fe-30Pt-30BN-10C) reveals the following. In the texture of Example 2 shown in FIG. 1, black (BN and C) is homogeneously dispersed in white (metal components: Fe, Pt), and the size of black (BN and C) is almost uniform. Meanwhile, in the texture of Comparative Example 3 shown in FIG. 2, relatively large flat black (BN and C) is unevenly distributed like strings in white (metal components: Fe, Pt), and the size of black is non-uniform.

TABLE 2
Measured Results of Examples and Comparative Examples

| | | Mixing conditions | | | | | | | | |
|---|---|---|---|---|---|---|---|---|---|---|
| | | | | | | | | Additional | | |
| | Composition | | | | | | | nonmetal | | |
| | Composition | Fe powder | | Pt powder | | BN powder | | component | | Additional |
| | mol % | | g | | g | | g | | g | component |
| Ex. 1 | Fe—31.5Pt—30BN | 7 μm | 190.28 | 1 μm | 543.83 | 4 μm | 65.90 | | | |
| Ex. 2 | Fe—30Pt—30BN—10C | 7 μm | 143.73 | 1 μm | 502.08 | 4 μm | 63.88 | C: 3 μm | 10.30 | |
| Ex. 3 | Fe—30Pt—30BN—10C | 7 μm | 143.73 | 1 μm | 502.08 | 4 μm | 63.88 | C: 3 μm | 10.30 | |
| Ex. 4 | Fe—31.5Pt—7Ag—30BN | 7 μm | 145.91 | 1 μm | 509.70 | 4 μm | 61.76 | | | Ag: 10 μm |
| Ex. 5 | Fe—31.5Pt—7Co—30BN | 7 μm | 151.43 | 1 μm | 528.97 | 4 μm | 64.10 | | | Co: 3 μm |
| Ex. 6 | Fe—31.5Pt—7Rh—30BN | 7 μm | 148.33 | 1 μm | 518.15 | 4 μm | 62.79 | | | Rh: 10 μm |
| Ex. 7 | Fe—39Pt—20BN—5SiO₂ | 7 μm | 153.66 | 1 μm | 581.50 | 4 μm | 37.94 | SiO₂: 2 μm | 22.96 | |
| Ex. 8 | Fe—35Pt—30BN | 7 μm | 172.79 | 1 μm | 603.60 | 4 μm | 65.83 | | | |
| Ex. 9 | Fe—32.5Pt—35BN | 7 μm | 157.91 | 1 μm | 551.60 | 4 μm | 75.58 | | | |
| Ex. 10 | Fe—27.5Pt—45BN | 7 μm | 129.51 | 1 μm | 452.40 | 4 μm | 94.19 | | | |
| Ex. 11 | Fe—35Pt—20BN—10C | 7 μm | 173.45 | 1 μm | 605.89 | 4 μm | 44.05 | C: 3 μm | 10.66 | |
| Ex. 12 | Fe—30Pt—30BN—10C | 7 μm | 143.73 | 1 μm | 502.08 | 4 μm | 63.88 | C: 3 μm | 10.30 | |
| Ex. 13 | Fe—30Pt—30BN—10C | 7 μm | 143.73 | 1 μm | 502.08 | 4 μm | 63.88 | C: 3 μm | 10.30 | |
| Ex. 14 | Fe—30Pt—30BN—10C | 7 μm | 143.73 | 1 μm | 502.08 | 4 μm | 63.88 | C: 3 μm | 10.30 | |
| Ex. 15 | Fe—25Pt—10Au—30BN—10C | 7 μm | 116.99 | 1 μm | 408.33 | 4 μm | 62.40 | C: 3 μm | 10.06 | Au: 1 μm |
| Ex. 16 | Fe—25Pt—10Ag—30BN—10C | 7 μm | 116.89 | 1 μm | 408.33 | 4 μm | 62.34 | C: 3 μm | 10.06 | Ag: 10 μm |
| Ex. 17 | Fe—25Pt—10Cu—30BN—10C | 7 μm | 121.19 | 1 μm | 423.33 | 4 μm | 64.63 | C: 3 μm | 10.43 | Cu: 3 μm |
| Ex. 18 | Fe—25Pt—10Rh—30BN—10C | 7 μm | 119.55 | 1 μm | 417.61 | 4 μm | 63.76 | C: 3 μm | 10.28 | Rh: 10 μm |
| Ex. 19 | Fe—25Pt—10Ge—30BN—10C | 7 μm | 112.65 | 1 μm | 393.51 | 4 μm | 60.08 | C: 3 μm | 9.69 | Ge: 10 μm |
| Comp. Ex. 1 | Fe—30Pt—30BN—10C | 7 μm | 143.73 | 1 μm | 502.08 | 4 μm | 63.88 | C: 3 μm | 10.30 | |
| Comp. Ex. 2 | Fe—30Pt—30BN—10C | 7 μm | 143.73 | 1 μm | 502.08 | 4 μm | 63.88 | C: 3 μm | 10.30 | |
| Comp. Ex. 3 | Fe—30Pt—30BN—10C | 7 μm | 143.73 | 1 μm | 502.08 | 4 μm | 63.88 | C: 3 μm | 10.30 | |
| Comp. Ex. 4 | Fe—30Pt—30BN—10C | 7 μm | 143.73 | 1 μm | 502.08 | 4 μm | 63.88 | C: 3 μm | 10.30 | |
| Comp. Ex. 5 | Fe—30Pt—30BN—10C | 7 μm | 143.73 | 1 μm | 502.08 | 4 μm | 63.88 | C: 3 μm | 10.30 | |

| | | | | | Particle size distribution | | | | |
|---|---|---|---|---|---|---|---|---|---|
| | | | Sintering | Sintering | of residue after dissolution | | | | |
| | Mixing conditions | | conditions | result | in aqua regia | | | | |
| | Additional | | Sintering | Relative | Number of | | | | 1 μm pass |
| | component | Mixing | temperature | density | particles | D10 | D50 | D90 | size % |
| | g | conditions | (° C.) | (%) | (—) | (μm) | (μm) | (μm) | (%) |
| Ex. 1 | | 150 rpm 4 h | 900 | 93.8 | 53 | 0.60 | 1.99 | 3.71 | 26.12 |
| Ex. 2 | | 150 rpm 4 h | 900 | 92.9 | 38 | 0.55 | 1.71 | 3.41 | 28.26 |
| Ex. 3 | | 150 rpm 2 h | 900 | 95.6 | 83 | 0.85 | 2.48 | 5.18 | 12.76 |
| Ex. 4 | 62.63 | 150 rpm 4 h | 900 | 95.2 | 49 | 0.66 | 1.82 | 3.60 | 27.50 |
| Ex. 5 | 35.51 | 150 rpm 4 h | 900 | 93.7 | 41 | 0.51 | 1.53 | 3.19 | 31.25 |
| Ex. 6 | 60.74 | 150 rpm 4 h | 900 | 92.5 | 43 | 0.64 | 1.99 | 3.75 | 27.24 |
| Ex. 7 | | 150 rpm 4 h | 1100 | 97.1 | 28 | 0.39 | 1.42 | 2.73 | 33.53 |
| Ex. 8 | | 150 rpm 3 h | 900 | 95.0 | 67 | 0.79 | 2.36 | 4.38 | 18.12 |
| Ex. 9 | | 150 rpm 3 h | 900 | 94.1 | 77 | 0.76 | 2.29 | 4.54 | 19.57 |
| Ex. 10 | | 150 rpm 3 h | 900 | 91.4 | 94 | 0.69 | 2.10 | 4.09 | 23.55 |
| Ex. 11 | | 150 rpm 3 h | 900 | 96.2 | 61 | 0.75 | 2.27 | 4.38 | 19.94 |
| Ex. 12 | | 150 rpm 3 h | 900 | 95.1 | 62 | 0.72 | 2.18 | 4.49 | 21.73 |
| Ex. 13 | | 150 rpm 3 h | 700 | 93.3 | 82 | 0.75 | 2.28 | 4.67 | 19.84 |
| Ex. 14 | | 150 rpm 6 h | 900 | 90.7 | 33 | 0.46 | 1.43 | 2.70 | 33.88 |
| Ex. 15 | 165.05 | 150 rpm 3 h | 900 | 96.1 | 55 | 0.78 | 2.34 | 4.58 | 19.28 |
| Ex. 16 | 90.31 | 150 rpm 3 h | 900 | 95.7 | 49 | 0.74 | 2.21 | 4.62 | 20.83 |
| Ex. 17 | 55.16 | 150 rpm 3 h | 900 | 95.9 | 66 | 0.73 | 2.20 | 4.63 | 21.38 |
| Ex. 18 | 88.12 | 150 rpm 3 h | 900 | 94.0 | 88 | 0.74 | 2.26 | 4.77 | 20.14 |
| Ex. 19 | 58.61 | 150 rpm 3 h | 700 | 97.0 | 60 | 0.76 | 2.31 | 4.29 | 19.43 |
| Comp. Ex. 1 | | 150 rpm 30 min | 900 | 95.4 | 563 | 1.72 | 3.72 | 6.34 | 5.21 |
| Comp. Ex. 2 | | 150 rpm 12 h | 900 | 87.4 | — | 0.43 | 1.34 | 2.48 | 36.29 |
| Comp. Ex. 3 | | 300 rpm 30 min | 900 | 91.4 | 713 | 0.69 | 2.13 | 5.72 | 21.85 |
| Comp. Ex. 4 | | 300 rpm 2 h | 900 | 86.5 | — | 0.35 | 1.32 | 4.57 | 36.58 |
| Comp. Ex. 5 | | 460 rpm 6 h | 900 | 79.2 | — | 0.38 | 1.11 | 2.35 | 40.16 |

*D10: volume-based 10% size or particle size (μm) at cumulative 10% value based on 100% for the total
D50: volume-based 50% size or particle size (μm) at cumulative 50% value based on 100% for the total
D90: volume-based 90% size or particle size (μm) at cumulative 90% value based on 100% for the total
<1 μm (%): cumulative percentage of particles having sizes that allow passing through of 1 μm sieve

1. An Fe—Pt—BN-based sputtering target comprising Fe, Pt, and BN, wherein a residue after dissolution in aqua regia has particle size distribution in which a volume-based 90% size (D90) is 5.5 μm or less and a proportion of fine particles smaller than 1 μm is 35% or less when the sputtering target is measured by a procedure below including:
(1) cutting out a 4 mm-square sample piece from the sputtering target and pulverizing the sample piece to prepare a pulverized product;
(2) classifying the pulverized product using sieves of 106 μm and 300 μm in opening size and collecting a powder that has passed through the 300 μm sieve and remained on the 106 μm sieve;
(3) immersing the powder in aqua regia heated to 200° C. to prepare a residue-containing solution in which the powder has been dissolved;
(4) filtering the residue-containing solution through a 5A filter paper specified in JIS P 3801 and drying a residue on the filter paper at 80° C. to prepare a residue powder;
(5) dispersing the residue powder in water containing a surfactant to prepare a sample solution; and
(6) setting the sample solution in a particle size analyzer and measuring particle size distribution.

2. The Fe—Pt—BN-based sputtering target according to claim 1, comprising 10 mol % or more and 55 mol % or less of Pt.

3. The Fe—Pt—BN-based sputtering target according to claim 1, further comprising
one or more elements selected from Ag, Au, B, Co, Cr, Cu, Ge, Ir, Ni, Pd, Rh, and Ru; and/or
one or more nonmetal components selected from C and an oxide of Si, Ti, Ta, or Zr.

4. The Fe—Pt—BN-based sputtering target according to claim 1, comprising:
10 mol % or more and 55 mol % or less of Pt;
10 mol % or more and 55 mol % or less of BN;
0 mol % or more and 20 mol % or less of one or more elements selected from Ag, Au, B, Co, Cr, Cu, Ge, Ir, Ni, Pd, Rh, and Ru;
0 mol % or more and 20 mol % or less of one or more nonmetal components selected from C and an oxide of Si, Ti, Ta, or Zr;
Wherein—10 mol % or more and 55 mol % or less in total of BN and one or more nonmetal components, and the balance is Fe and an incidental impurities and the total amount of Pt, BN, one or more elements, one or more nonmetal components, Fe and the incidental impurities is 100 mol %.

5. A production method for the Fe—Pt—BN-based sputtering target according to claim 1, comprising
feeding Fe powder, Pt powder, and BN powder into a stirred media mill and mixing at 100 rpm or more and 200 rpm or less for 2 hours or more and 6 hours or less to prepare a raw material powder mixture;
collecting, from the raw material powder mixture, a power that has passed through a sieve of 300 μm in opening size; and
sintering the powder.

6. The production method according to claim 5, wherein the sintering is performed at a sintering temperature of 600° C. or higher and 1,200° C. or lower and a sintering pressure of 30 MPa or more and 200 MPa or less.
